(19) United States
(12) Patent Application Publication
(10) Pub. No.: US 2022/0113601 A1
(43) Pub. Date: Apr. 14, 2022

(54) MANUFACTURING METHOD FOR MICRO DISPLAY BOARD

(71) Applicant: SHIN-ETSU CHEMICAL CO., LTD., Tokyo (JP)

(72) Inventors: Yuji TOBISAKA, Annaka-shi (JP); Shigeru KONISHI, Annaka-shi (JP); Makoto KAWAI, Annaka-shi (JP)

(21) Appl. No.: 17/419,017

(22) PCT Filed: Dec. 26, 2019
(86) PCT No.: PCT/JP2019/051242

§ 371 Date: Jun. 28, 2021

(30) Foreign Application Priority Data
Jan. 8, 2019 (JP) 2019-001329

(51) Int. Cl. G02F 1/1362

(52) U.S. Cl. CPC G02F 1/136295; G02F 1/136209; G02F 1/136277

(57) ABSTRACT

A transmissive micro display board is manufactured without providing a light shielding layer. A manufacturing method of a micro display board includes the steps of: (i) forming a circuit layer on a surface of a first substrate provided with a single-crystal silicon layer; (ii) attaching a second substrate by using an adhesive to the surface of the first substrate on which the circuit layer has been formed; (iii) thinning a rear surface of the first substrate; (iv) attaching a third substrate being a transparent substrate to the thinned surface of the first substrate by using an adhesive; (v) removing the second substrate from the first substrate; and (vi) exposing a surface of the circuit layer by removing the adhesive on the surface of the first substrate after detaching the second substrate. The step (i) includes the steps of forming an active layer, a gate layer, and a wiring layer in turn, and the wiring layer is provided to satisfy such a positional relation that the wiring layer shields the active layer and the gate layer from incident light.

### TECHNICAL FIELD

The present invention relates to a manufacturing method for a micro display board.

### BACKGROUND ART

Liquid crystal panels are generally used as display devices used as display units of televisions and personal computers, as portable terminals, and the like. Such display devices include those projecting images, such as projectors, in addition to those allowing direct view of a display panel. There are head-up displays (HUD) and head-mounted displays (HMD) serving as small-size display devices. A head-mounted display that is reduced in size so as to be of the eyeglasses type is called “smartglasses”.

Undersized display devices called micro displays are used in those small-size display devices including projectors. Video images of such micro displays are enlarged and projected onto a screen so as to be viewable by viewers, or micro displays are designed to guide video images to the field of vision of a viewer through a reflecting member. Among them, the head-mounted display is drawing attention as one of the wearable terminals thanks to the ability to view information obtained through an information terminal in a hands-free manner. The head-mounted display is worn like eyeglasses so as to present displays near the eyes (see Patent Documents 1 and 2, for example). Accordingly, there is a demand to reduce the size of the device itself.

Reduced size display devices called micro displays are used in the head-mounted displays. These display devices include a transmissive liquid crystal panel that controls transmitted light with a liquid crystal, a reflective liquid crystal panel that reflects light with an electrode unit and controls a direction of polarization of the reflected light with a liquid crystal, and a micro mirror drive panel that controls the directions of reflected light from micro mirrors.

Each of the panels mentioned above refers to a single panel component. In actuality, a display device requires a light source, optical components for guiding the light to the panel, optical components for guiding outgoing light to an output side, and so forth. The transmissive liquid crystal panel emits incident light without changing its direction. Accordingly, it is possible to simplify optical systems in front of or behind the panel, and thus to make the display device in a compact size. The reflective liquid crystal panel outputs the reflected light. Here, it is necessary to split the light by using an optical component called a polarizing beam splitter (PBS) because incident light and outgoing light are on the same side of the panel surface. As a consequence, this display device is increased in size. The micro mirror drive panel also requires an optical component (such as a total internal reflection prism (TIR prism)) for utilizing reflected light and this display device is increased in size.

The transmissive liquid crystal panel has a similar structure to that of the direct view type liquid crystal panel that performs the display for a liquid crystal television or a portable terminal such as a smartphone. Nonetheless, the micro display requires an extremely small pixel size in order to form the number of pixels necessary for display in a size equal to or below 1 inch. For example, a width of each pixel is about 10 μm in a case of forming 680×480 pixels on a panel having a diagonal length of 0.3 inch. A width of each pixel is about 3.5 μm in a case of forming 1280×720 pixels on a panel having a diagonal length of 0.2 inch. Here, a display unit has a size of 4.4×2.5 mm. The latter is the size required for displaying high-definition television image quality on the smartglasses, which involves extremely small pixels. A method of constructing pixel circuits of this size is limited to a semiconductor manufacturing process that adopts single-crystal silicon (hereinafter also referred to as single-crystal Si), and such pixel circuits cannot be achieved by a manufacturing process used for ordinary liquid crystal panels which mainly adopts low-temperature polycrystalline silicon or high-temperature polycrystalline silicon.

A liquid crystal panel adopting the single-crystal Si is referred to as LCOS (liquid crystal on silicon) and is described distinctively from an ordinary liquid crystal display (LCD). A Si substrate or an SOI (silicon on insulator) substrate is normally used when the pixel circuits are formed from the single-crystal Si. However, Si cannot be directly used as a display device because Si does not transmit light. It is optimal to use an SOQ (silicon on quartz) substrate, which is prepared by depositing a single-crystal Si film on a quartz glass substrate, for micro displays because it is possible to form small-size transistors thereon and to allow light to pass through the portions not provided with the pixel circuits. Nevertheless, the semiconductor process adopting the single-crystal Si cannot be simply used therein because the process has to deal with a substrate that transmits light. For this reason, it is necessary to form the pixel circuits by using the Si or SOI substrate and then to impart a light transmission property to the portions other than the pixel circuits.

There has been disclosed a method of forming a pixel circuit board by forming a pixel circuit on an SOT substrate, attaching a circuit portion to a transparent substrate by using an adhesive, and then removing the SOI substrate (see Patent Document 3, for example). In this way, it is possible to use ordinary semiconductor processing equipment, to form circuits that are small in size and high in performance, and to use the circuits for a transmissive liquid crystal panel.

When the circuits are formed on the light transmissive substrate, it is known that transistors are also illuminated with the light whereby a photo-leakage current flows thereon and adversely affects properties of the transistors. It is also known that this phenomenon is significant in the case of amorphous Si and adverse effects can be reduced by improving crystallinity or by changing a structure of the transistors. Patent Document 3 discloses formation of a light shielding layer, and thus solves the problem.

### REFERENCE DOCUMENT LIST

### Patent Documents

Patent Document 1: JP 5678460 B

Patent Document 2: JP 2010-32997 A

Patent Document 3: U.S. Pat. No. 5,256,562

### SUMMARY OF THE INVENTION

### Problems to Be Solved by the Invention

As discussed above, the SOQ substrate is thought to be used for manufacturing the micro display board. However, the SOQ substrate has two problems when used in ordinary semiconductor processing equipment. One of the problems is that a sensor using light for checking the presence of the substrate does not detect the substrate because of its light transmissive property. The other is that an electrostatic chuck used in the semiconductor processing equipment cannot chuck the substrate. The semiconductor processing equipment needs to be modified due to these problems, and it is not possible to place the substrate directly into all of the semiconductor processing equipment. At present, the semiconductor processing equipment especially adjusted in order to form the circuits on the SOQ substrate is limited to a system adapted to a substrate having a small-diameter size such as an outside diameter of 150 mm. There is a problem in that the semiconductor processing equipment is not adaptable to a substrate having a large-diameter size such as an outside diameter of 200 mm.

Either the Si substrate or the SOI substrate has to be used in order to apply the semiconductor process to the large diameter, and the abovementioned method disclosed in Patent Document 3 is conceivable, However, the method disclosed in Patent Document 3 requires a process for forming a light shielding film made of an opaque material such as aluminum or chromium. Accordingly, there are problems of an increase in cost and reduction in yield.

The increase in cost involves not only the formation of the light shielding film but also a need to pass wiring through the light shielding film in the case in which a transparent electrode is formed as a pixel electrode on the light shielding film. This complicates the pattern. In other words, there is a problem of increase in number of processes.

Concerning the reduction in yield, there is a description in Patent Document 3 concerning the formation of the light shielding film on a bottom side of a transistor (on an opposite side of the wiring layer relative to the transistor). In this process, there is a concern of occurrence of a patterning defect and a defect of final adhesion to a supporting board. As for the patterning detect, there are a risk of occurrence of an anomaly in reading an alignment mark due to an effect of irregularity developed on a surface due to adhesion for temporary bonding at the time of forming the light shielding film, and a risk of a failure to form an intended pattern due to loss of focus at the time of exposure. There is also a concern of a case in which the circuit partially deviates from the alignment mark. Such a deviation may take place due to the occurrence of irregularity on the surface due to a variation in thickness direction of the circuit since the temporary bonding is conducted by adhesion and the light shielding film is formed after reducing the thickness of the temporarily bonded body. A displacement may possibly occur due to warpage at the time of attachment.

As for the defect of final adhesion to the supporting board, when the light shielding film is formed at the position of the transistor that is reduced in thickness after temporarily bonding a first board, a difference in level is inevitably formed because the light shielding film has a thickness. Although the thickness is as small as about 100 to 500 nm, it is desirable to attach a circuit unit to a third supporting board by using a thin adhesive layer in order to eliminate optical effects. The difference in level is prone to entrap an air bubble at the time of adhesion, and the product will be defective if an air bubble is trapped therein.

From these points, the light shielding film must be formed efficiently, and there is a demand for forming the light shielding film at high accuracy without additional processes.

### Means for Solving the Problems

An embodiment of the present invention relates to a manufacturing method of a micro display board, which includes the steps of: (i) forming a circuit layer on a surface of a first substrate provided with a single-crystal silicon layer; (ii) attaching a second substrate by using an adhesive to the surface of the first substrate on which the circuit layer has been formed; (iii) thinning a rear surface of the first substrate; (iv) attaching a third substrate being a transparent substrate to the thinned surface of the first substrate by using an adhesive; (v) removing the second substrate from the first substrate; and (vi) exposing a surface of the circuit layer by removing the adhesive on the surface of the first substrate after detaching the second substrate. Here, the step of forming a circuit layer on the first substrate includes the steps of forming an active layer, a gate layer, and a wiring layer, and the wiring layer forms a light shielding layer by being provided to satisfy such a positional relationship that the wiring layer shields the active layer and the gate layer from incident light from an opposite side of the active layer.

Another aspect of the present invention relates to a transmissive micro display board, which includes: a transparent substrate; an insulating layer originating from an SOI wafer; and a circuit layer, in which the insulating layer and the circuit layer are stacked, in this order, on the transparent substrate by using an adhesive. Here, the circuit layer includes an active layer, a gate layer, and a wiring layer, which are located on the insulating layer, and the wiring layer forms a light shielding layer by being provided to satisfy such a positional relationship that the wiring layer shields the active layer and the gate layer from incident light from an opposite side of the transparent substrate.

### Effects of the Invention

According to the manufacturing method of the present invention, it is possible obtain a micro display board to be used in a transmissive liquid crystal panel without requiring the separate step of forming a light shielding layer made of a metal such as aluminum, which has previously been essential for avoiding exposure of a transistor to light. The micro display board obtained in accordance with this manufacturing method can achieve a favorable operation as a transmissive liquid crystal panel without an effect of a photo-leakage current and the like.

### BRIEF DESCRIPTION OF THE DRAWINGS

FIG. 1 is a diagram schematically illustrating a process of a manufacturing method of a micro display board of the present invention.

FIG. 2 is a diagram schematically illustrating a cross-sectional structure of a pixel circuit in the micro display board of the present invention.

FIGS. 3A and 3B are schematic diagrams of an active matrix.

FIG. 4 is a diagram schematically illustrating an example of planar arrangement of active (Si) in a transistor region.

FIG. 5 is a diagram schematically illustrating an example of planar arrangement of gates (polycrystalline silicon) in the transistor region.

FIG. 6 is a diagram schematically illustrating an example of planar arrangement of a first wiring layer.

FIG. 7 is a diagram schematically illustrating an example of planar arrangement of a second wiring layer.

FIG. 8 is a diagram schematically illustrating an example of planar arrangement of the first wiring layer and the second wiring layer.

FIG. 9 is a diagram schematically illustrating an example of planar arrangement of the first wiring layer, the second wiring layer, and a pixel electrode (a transparent electrode).

FIG. 10 is a diagram schematically illustrating a structure of a liquid crystal panel.

FIG. 11 is a diagram schematically illustrating an example of a circuit layout of the liquid crystal panel.

FIG. 12 is a diagram schematically illustrating an example of a circuit layout on a pixel substrate.

### MODES FOR CARRYING OUT THE INVENTION

Embodiments of the present invention will be described below with reference to the drawings. It is to be noted, however, that the present invention shall not be limited only to the embodiments described below.

### First Embodiment: Manufacturing Method of Micro Display Board

A first embodiment of the present invention relates to a manufacturing method of a micro display board. The manufacturing method includes the following steps (i) to (vi) of:

(i) forming a circuit layer on a surface of a first substrate provided with a single-crystal silicon layer;

(ii) attaching a second substrate to the surface of the first substrate on which the circuit layer has been formed by using an adhesive;

(iii) thinning a rear surface of the first substrate;

(iv) attaching a third substrate to the thinned surface of the first substrate by using an adhesive, the third substrate being a transparent substrate having a substantially identical outline to the second substrate;

(v) removing the second substrate from the first substrate; and

(vi) exposing a surface of the circuit layer by removing the adhesive on the surface of the first substrate after detaching the second substrate.

In this manufacturing method, the step (i) includes the steps of forming an active layer from the single-crystal silicon layer by doping the single-crystal silicon layer with an impurity, and then forming a gate layer by depositing polycrystalline silicon into a film, and forming a metal wiring layer. The wiring layer forms a light shielding layer by being provided to satisfy such a positional relationship that the wiring layer shields the active layer and the gate layer from incident light from an opposite side of the active layer and the gate layer relative to the wiring layer.

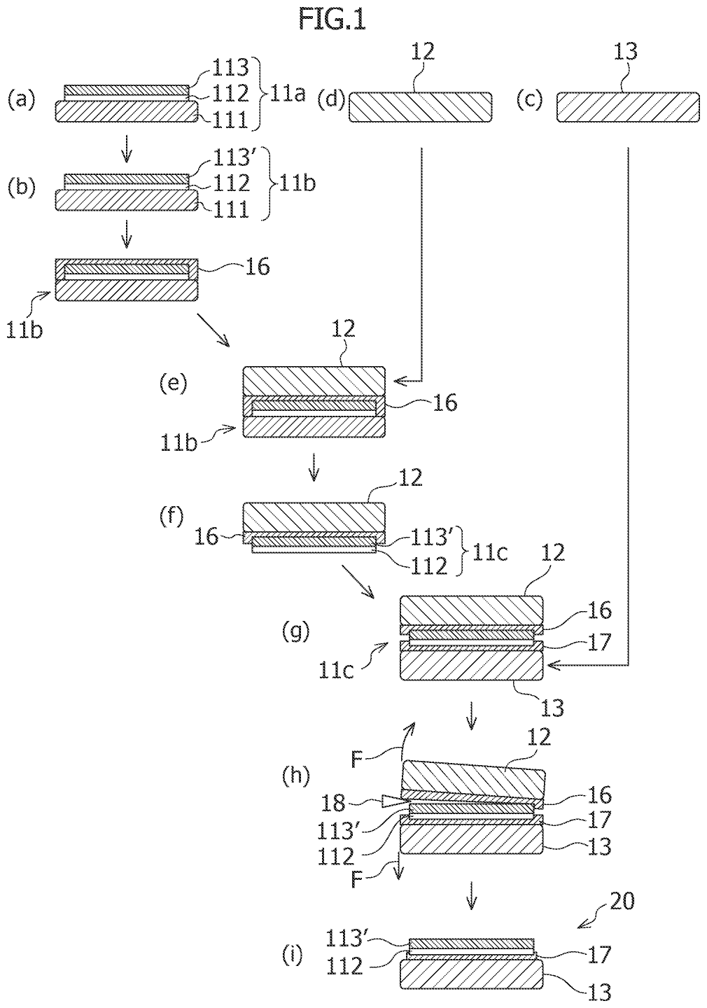

A description will be given of a micro display board to be obtained by the manufacturing method of this embodiment. The micro display board is a board including a circuit layer that includes an active layer, a gate layer, and a wiring layer, and may also optionally include a pixel electrode, and that is formed on a transparent substrate. The micro display board is used in a transmissive micro display. In a preferable embodiment, the micro display board is a board obtained by bonding an insulator layer manufactured as an SOI (silicon on insulator) wafer as well as the circuit layer provided on the insulator layer to the transparent substrate through an adhesive layer. FIG. 1 shows diagrams conceptually describing the manufacturing method of this embodiment, in which FIG. 1(i), is a diagram illustrating an example of the micro display board to be manufactured. In a micro display board 20 illustrated therein, a third substrate 13 being a transparent substrate, an adhesive layer 17, an insulator layer 112, and a circuit layer 113′ are stacked, in this order.

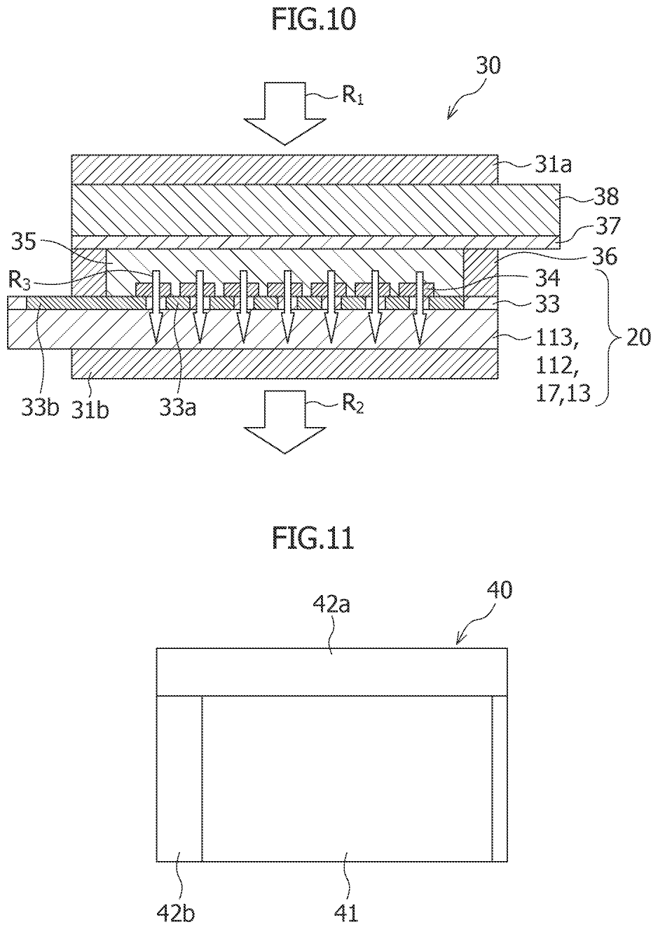

The micro display board described above can be formed into a liquid crystal panel by attaching this substrate to another substrate provided with a counter electrode, cutting the combined substrates into a size of a panel, and then sealing a liquid crystal therein. FIG. 10 illustrates a schematic structure of the liquid crystal panel described above. In FIG. 10, a layer including a pixel electrode 34, a circuit 33 including a transistor region made of single-crystal silicon and a wiring layer, the insulator layer 112, the adhesive layer 17, and the third substrate 13 is a pixel substrate and this pixel substrate constitutes the micro display board 20. In a liquid crystal panel 30 illustrated in FIG. 10, a counter electrode 37 and a counter substrate 38 are arranged on the pixel electrode 34 side of the micro display board 20 with a spacer 36 interposed in between. A space between the counter electrode 37 and the pixel electrode 34 is filled with a liquid crystal 35. A first deflection plate 31a is provided on a principal surface of the counter substrate 38 located on an opposite side from the counter electrode 37 while a second deflection plate 31b is provided on a principal surface on the third substrate side of the micro display board 20. The above-described liquid crystal panel 30 is combined with a light source (not shown) and formed into the micro display. In this instance, the directions of light R₁ emitted from the light source and of light R₂ passing through the liquid crystal panel 30 are restricted to the directions from the first deflection plate 31a toward the second deflection plate 31b.

Circuit patterns are formed on the pixel substrate. FIG. 11 is a diagram conceptually illustrating a circuit pattern. A circuit pattern 40 includes a pixel section 41, a column selection circuit 42a, and a row selection circuit 42b. The pixel section 41 in FIG. 11 corresponds to a portion through which light passes in FIG. 10, and the column selection circuit 42a and the row selection circuit 42b located around the pixel section 41 form a peripheral circuit 33b in FIG. 10. The transistor region made of the single-crystal Si and the wiring layer connected thereto constitute a pixel circuit 33a in FIG. 10. In FIG. 10, light R₃ passes through a portion in which the pixel circuit 33a is not present, or in other words, a space between every two pixel circuits 33a located adjacent to each other.

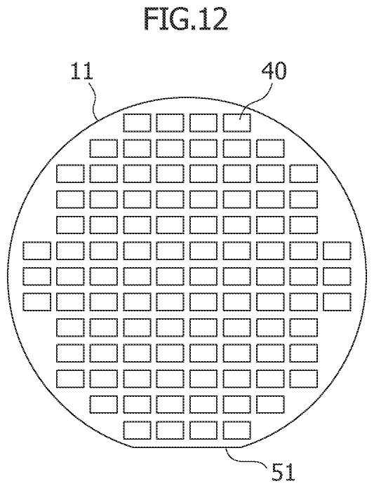

The circuit patterns 40 illustrated in FIG. 11 are arranged on the entire surface of the pixel substrate. FIG. 12 is a diagram conceptually illustrating the substrate on which the circuit patterns are arranged (formed) on the entire surface. Multiple circuit patterns can be arranged on the entire surface of a single first substrate 11, which is a substrate such as an SOI substrate provided with an orientation flat 51 at a portion on its outer edge. Thus, it is possible to form a large number of circuit patterns 40. The circuit 40 including the pixel circuit 41 and the peripheral circuits 42a and 42b corresponds to each liquid crystal panel. As illustrated in FIG. 12, a large number of panels can be formed from one substrate.

FIGS. 3A and 3B are diagrams for explaining an outline of circuits in the circuit patterns 40 illustrated in FIG. 11. FIG. 3A illustrates an outline of circuits adopting an active matrix driving mode, and FIG. 3B is an enlarged schematic diagram of a portion A in FIG. 3A. In FIG. 3A, multiple column selection signal lines Cl (also referred to as data lines) coupled to sources of the pixel circuits are extended from the column selection circuit 42a and arranged in the vertical direction, and multiple row selection signal lines R coupled to gates of the pixel circuits are extended from the row selection circuit 42b and arranged in the horizontal direction. With reference to FIG. 3B, a thin layer transistor (a field effect transistor) is provided at each of intersections A thereof, in which the column selection signal line CI is coupled to a source of the thin layer transistor, the row selection signal line R is coupled to the gate thereof, and a liquid crystal electrode L as well as an auxiliary capacitance (such as a transistor and a capacitor) Ca are coupled to a drain thereof. Here, the column selection circuit 42a is a first wiring layer made of a metal. The row selection signal line R is made of polycrystalline silicon and forms a gate layer.

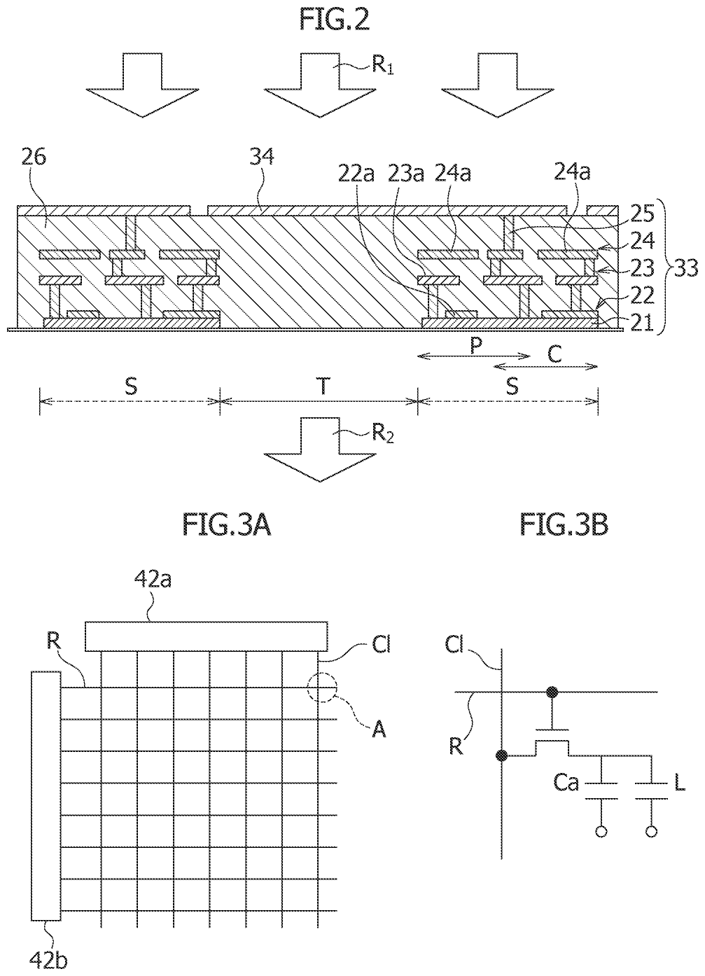

Next, a cross-sectional structure of the circuit layer will be schematically described with reference to FIG. 2. FIG. 2 is a schematic cross-sectional view of a portion corresponding to the circuit 33 and the pixel electrode 34 in FIG. 10. In the circuit 33, an active layer 21 formed by doping a single-crystal silicon layer with an impurity, a gate layer 22 formed by depositing polycrystalline silicon into a film, a first wiring layer 23, and a second wiring layer 24 are provided in this order. The active layer 21 and the gate layer 22 are collectively referred to as a transistor region. These layers are insulated from one another by an insulating film 26, and wiring 25 is formed by piercing contact holes for electrically coupling these layers and burying metal in the contact holes, whereby the layers are coupled to one another through the wiring 25. A transparent electrode serving as the pixel electrode 34 is provided on a surface on an opposite side of the second wiring layer 24 from the transistor region. When referring to the circuit layer, this pixel electrode 34 may also be included therein in some cases. In FIG. 2, reference symbol R₁ denotes the light emitted from the light source and made incident on the circuit 33 and reference symbol R₂ denotes the light passing through the circuit 33, and the directions thereof are in line with the direction from the pixel electrode 34 toward the transistor region. The first wiring layer 23 and the second wiring layer 24 shield the active layer 21 and the gate layer 22 in the transistor region from the incident light R₁. Specifically, a region in which the first wiring layer 23 and the second wiring layer 24 are present constitutes a light shielding portion S and a portion in which the first wiring layer 23 and the second wiring layer 24 are not present constitutes a light transmissive region T. The light shielding portion S corresponds to one pixel. In FIG. 2, reference symbol 22a corresponds to a row selection line, reference symbol 23a corresponds to a column selection signal line, and reference symbol 24a corresponds to ground (GND). Reference symbol P denotes a region of a pixel selection circuit and reference symbol C denotes a region of the auxiliary capacitance for applying charges to the liquid crystal.

In the circuit 33, the first wiring layer 23 and the second wiring layer 24 are metal layers which do not transmit light. Although the wiring layer includes two layers of the first wiring layer and the second wiring layer in the illustrated embodiment, the present invention is not limited only to this embodiment. The wiring layer may include three or more layers. As illustrated in FIG. 2, it is possible to shield the transistor region from light by arranging the wiring layers 23 and 24 in such a way as to cover the active layer 21 and the gate layer 22 in the transistor region. This structure makes it unnecessary to form a light shielding layer separately, and makes it possible to reduce costs. As illustrated in FIGS. 2 and 10, light is emitted in a direction from the pixel electrode 34 side to the transistor region. In other words, the directions of the incident light R₁ and the transmitted light R₂ are restricted to the illustrated direction, and only the light in this direction needs to be blocked.

Arrangement for concealing the abovementioned transistor region can be achieved by designing an arrangement in such a way that the first wiring layer 23 and the second wiring layer 24 make the transistor region invisible in plan view, from the incident light R₁ side, of the circuit 33 in which the active layer 21, the gate layer 22, the first wiring layer 23, and the second wiring layer 24 are stacked, and then manufacturing these constituents in accordance with the design. In this instance, the case in which a line indicating an outer edge of the wiring layer overlaps a line indicating an outer edge of the transistor region in the plan view of the circuit 33 from the incident light R₁ side is also included in the “concealing arrangement”. The concealing arrangement also includes the case in which the wiring layer bulges outward from the outer edge of the transistor region in the plan view of the circuit 33 from the incident light R₁ side. In the case in which two or more wiring layers constitute the arrangement for collectively concealing the transistor region, there may be a portion in which the first wiring layer overlaps the second wiring layer when drafting the plan view from the incident light R₁ side. Here, the arrangement may be configured to form a boundary between the first wiring layer and the second wiring layer, formed of an overlap between a line indicating an outer edge of the first wiring layer and a line indicating an outer edge of the second wiring layer, and to shield the transistor region from the incident light R₁ by using the first wiring layer and the second wiring layer in an integrated fashion.

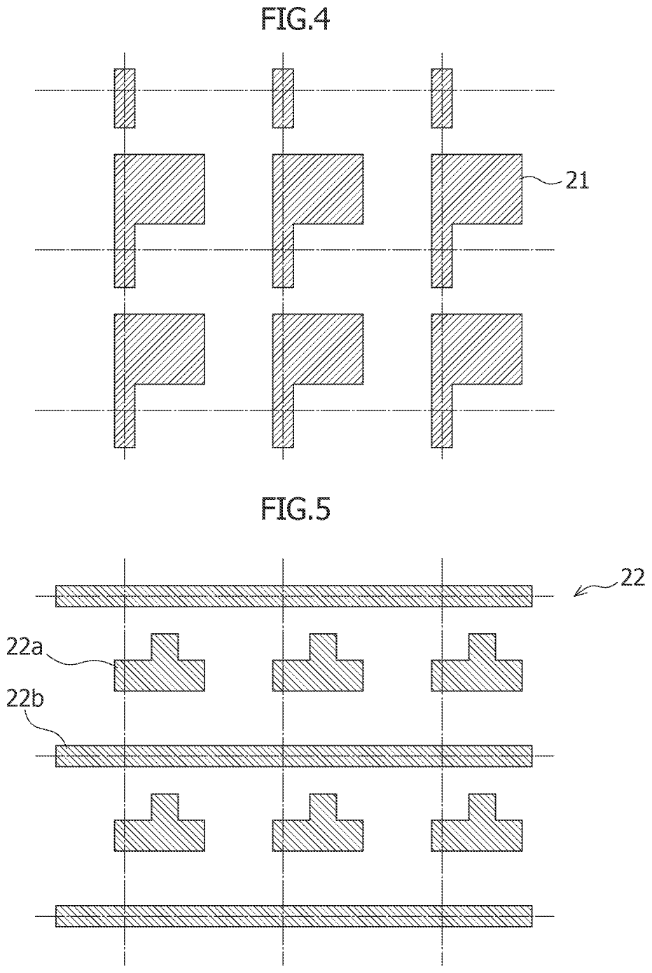

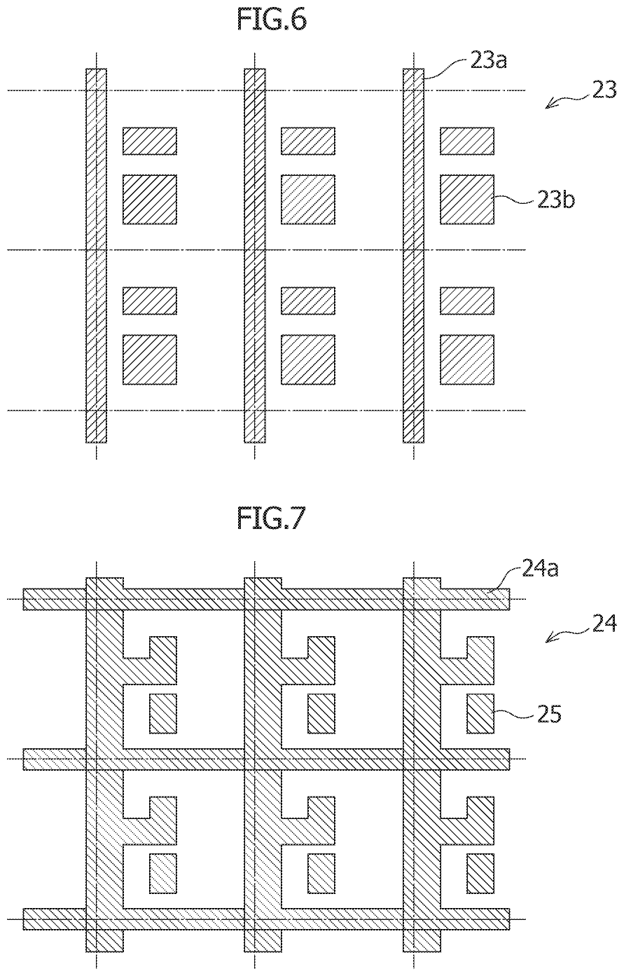

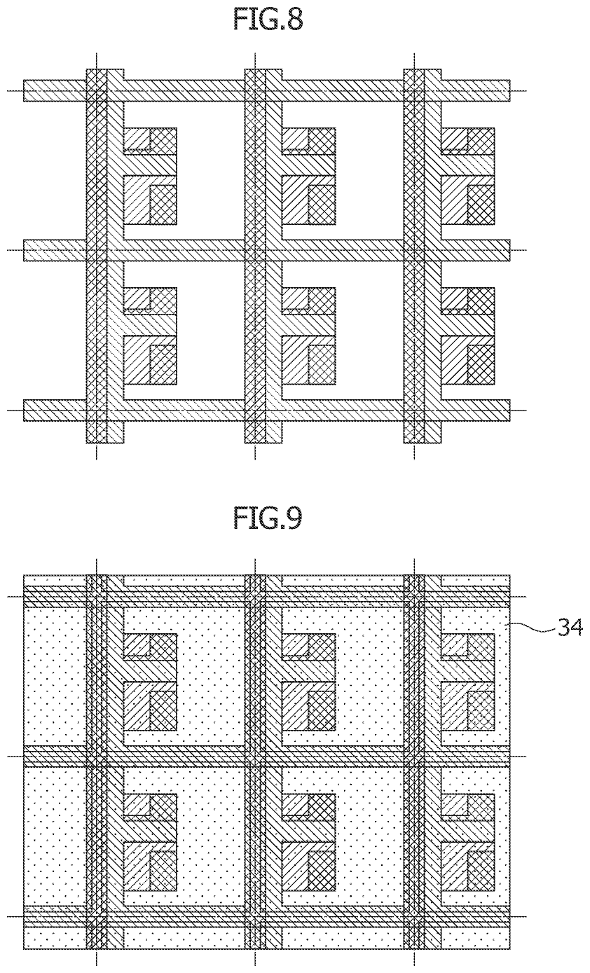

Specific arrangement of the circuits 33 is illustrated in FIGS. 4 to 9. FIG. 4 illustrates planar arrangement of the active layers 21 of the transistors, FIG. 5 illustrates planar arrangement of the gate layers 22 thereof, FIG. 6 illustrates planar arrangement of the first wiring layers 23 thereof, and FIG. 7 illustrates planar arrangement of the second wiring layers 24 thereof. FIG. 8 is a plan view of the first wiring layer 23 on which the second wiring layer 24 is overlaid, which is a plan view from the incident light R₁ side in FIG. 2 or FIG. 10. FIG. 9 is a plan view of a transparent electrode ITO representing an example of the pixel electrode 34, further overlaid on the FIG. 8, which is a plan view from the incident light R₁ side in FIG. 2 or FIG. 10. The reference symbols in these figures correspond to the configuration described with reference to FIG. 2. By appropriately arranging the first wiring layer 23 and the second wiring layer 24 as illustrated in FIG. 8, it is possible to conceal the active layer 21 illustrated in FIG. 4 and the gate layer 22 illustrated in FIG. 5, which collectively constitute the transistors, from the incident light R₁. Here, the first and second wiring layers 23 and 24 serve as a light shielding layer.

A manufacturing method according to the present invention will be described below with reference to FIG. 1. FIG. 1 is a view schematically illustrating the manufacturing method of the present invention. Now, a description will be given in accordance with operating steps. A first substrate illustrated in FIG. 1(a), a second substrate illustrated in FIG. 1(b), and a third substrate illustrated in FIG. 1(c) are prepared when implementing the manufacturing method of this embodiment. The first substrate is not limited to a particular substrate as long as the substrate includes a single-crystal silicon layer that allows formation of the circuits on the surface thereof, and an SOI substrate can preferably be used therefor. In the following explanation, an SOI substrate is used as an example of the first substrate. For any type of substrate, the thickness of the single-crystal silicon layer can be determined by circuit design and processing conditions. A first substrate 11a illustrated in FIG. 1(a) is a substrate manufactured as an SOI wafer and is a substrate on which the insulator layer 112 and a single-crystal silicon layer 113 are stacked, in this order, on a silicon substrate 111. In this specification, the silicon substrate 111 may also be referred to as a rear surface silicon layer when appropriate, The “rear surface” is assumed to represent a relative position in a case in which either the single-crystal silicon layer 113 or the circuit layer including the active layer originating therefrom is regarded as a front surface. The insulator layer 112 is a layer of a buried oxide film (SiO₂), and a thickness thereof may usually be set in a range from about 50 to 500 nm. The single-crystal silicon layer 113 is an active layer formed from the single-crystal silicon (Si).

The third substrate 13 illustrated in FIG. 1(c) is a colorless transparent substrate because it is the substrate to which the circuit layer is eventually transferred and is required to let light pass through as the micro display. The colorless transparent substrate in the present invention is assumed to be a substrate having a transmission rate of 80% or more, or preferably 90% or more for visible light having wavelengths in a range from about 400 to 700 μm. Quartz glass may be used for the third substrate 13. Alternatively, either alkali-free glass or optical glass applicable to ordinary liquid crystal panels may be used instead.

A second substrate 12 illustrated in FIG. 1(d) is a substrate to be temporarily bonded to the first substrate. The second substrate 12 and the third substrate 13 are preferably made of the same material so as to prevent the occurrence of a heat stress at the time of heating and curing an adhesive when the third substrate 13 is attached. An outside diameter of the second substrate 12 is preferably substantially equal to an outside diameter of the third substrate 13, or more preferably equal thereto in order to facilitate positioning when attaching the third substrate and to equalize pressure application at the time of the adhesion. If the outside diameters of the second substrate and the third substrate are different, then it is necessary to provide a positioning mechanism for this purpose or to prepare a jig for applying a pressure to an area in which the second substrate does not overlap the third substrate, and such a remedy may potentially trigger a deterioration in quality at the time of adhesion.

(i) Step of Forming Circuit Layer

In the step (i), the circuit layer is formed on the SOI substrate 11a illustrated in FIG. 1(a) by using the semiconductor process. The formation of the circuit layer can be carried out in accordance with a method generally used in the semiconductor process. Specifically, the circuit 33 is formed in accordance with a method including the steps of forming the active layer 21 by doping the single-crystal silicon layer 113 of the SOI substrate 11a with the impurity, forming the gate layer 22 by depositing polycrystalline silicon into a film on the active layer 21, and forming the first wiring layer 23 and then the second wiring layer 24. After the formation of the circuit 33, it is possible to form the transparent electrode constituting the pixel electrode 34, or typically an ITO (indium tin oxide) layer, and to carry out pattern formation thereof. Film deposition at a high temperature or a thermal treatment after the film deposition is required in order to improve properties such as resistance of the ITO film. Accordingly, it is preferably to form the ITO film in a state in which the circuit 33 is present on the first substrate. Here, the step of forming the ITO film of the pixel electrode 34 can also be included in the step of forming the circuit layer. It is also possible to optionally form a protection film on the pixel electrode 34 after completion of this step, because the protection film can prevent damage in the following steps. The protection film is preferably made of a photoresist used for transistor formation because the formed pixels are as small as several micrometers and each groove between the ITO electrodes is 1 μm or less, so that removal of the protection layer at the groove portions needs to be secured. Instead, the formation of the protection film can be carried out at the time of coating the adhesive before the attachment.

As for the structure of the circuit 33, the first wiring layer 23 and the second wiring layer 24 of each pixel are arranged in such a way as to conceal the transistor region as mentioned above. As discussed earlier, the example of arrangement of the active layer 21, the gate layer 22, the first wiring layer 23, and the second wiring layer 24 is as illustrated in FIGS. 4 to 9. In this way, it is not necessary to provide the light shielding film between the circuit 33 and the pixel electrode 34 after the formation of the circuit 33, and the process can be simplified and the yield can be improved. Here, in a case in which the light shielding film is additionally provided, it is necessary to subject the light shielding film to patterning after the formation of the circuit 33 and before the formation of the transparent electrode serving as the pixel electrode 34. In this case, contact portions to electrically couple the circuit 33 to the pixel electrode 34 on the superficial layer have to be provided in such a way as to penetrate the light shielding film, whereby designing and the patterning process of the light shielding film are complicated. FIG. 1(b) schematically illustrates a first substrate 11b provided with the circuits and the pixel electrodes.

(ii) Step of Attaching Second Substrate to First Substrate

In the step (ii), the second substrate is attached, using adhesive, to the first substrate 11b on which the circuit layer is formed, and onto the surface provided with the circuit layer. This step corresponds to a step of temporarily bonding the second substrate to the first substrate for a step of grinding the first substrate in the subsequent step (iii). Accordingly, this step can also be referred to as a temporary bonding step.

An adhesive that is capable of withstanding the grinding in the subsequent step (iii) and is removable after attachment to the third substrate in the step (iv) is selected in this step. As for such a temporary bonding adhesive 16, it is possible to use an adhesive which is resistant to a chemical solution used in grinding and is easily peeled or detached. For example, it is possible to use a temporary bonding adhesive 16 composed mainly of UV curable acrylic adhesive or thermosetting modified silicone. However, the adhesive is not limited only to these components. As for a specific example of the former substance, it is possible to use WSS (manufactured by 3M) and the like. As for specific examples of the latter substance, it is possible to use TA1070T/TA2570V3/TA4070 (manufactured by Shin-Etsu Chemical Co., Ltd.), and the like. The product TA1070T can serve as an adhesive layer for circuit protection, the product TA2570V3 can serve as an adhesive layer for forming a stripped surface, and the product TA4070 can serve as an adhesive layer to the second substrate 12. In particular, it is preferable to use a temporary bonding adhesive 16 composed mainly of the latter thermosetting modified silicone in light of resistance to the chemical solution.

In this step, the temporary bonding adhesive 16 is coated in a thickness of about 5 to 100 μm by spin coating on the surface provided with the circuit layer of the first substrate 11b on which the circuit layer has been formed, and/or one of the principal surfaces of the second substrate 12. Then, temporary adhesion can be achieved by subjecting the used temporary bonding adhesive 16 to UV irradiation or heating in accordance with conditions of use of the adhesive. It is preferable to coat the adhesive in such a way as to cover not only the surface provided with the circuit layer but also side surfaces of the circuit layer as well as side surfaces of the insulator layer 112. Thus, a bonded body illustrated in FIG. 1(e) is obtained.

(iii) Step of Thinning

This step includes the step of grinding and thinning the silicon substrate layer (the rear surface silicon layer) 111 of the first substrate 11b in the bonded body obtained in the step (ii), and the step of removing the silicon substrate 111 remaining after the grinding and thinning step by etching.

In the grinding and thinning step, the silicon substrate 111 can undergo processing for thinning by using a combination of different types of grindstones, for example. It is preferable to leave the silicon substrate 111 in a thickness of about 10 to 100 μm. Subsequently, edge trimming is carried out. A portion at a length of about 2 to 5 mm from an edge of the SOI water 11b is removed together with the temporary bonding adhesive 16. Examples of such an edge trimming method include grinding with a grinder, tape grinding by using an abrasive film, and the like. The tape grinding is preferable in particular.

Following the edge trimming, etching is carried out in order to remove the remaining silicon substrate layer 111. FIG. 1(f) is a diagram conceptually illustrating the bonded body of the second substrate 12 and a thinned first substrate 11c after completely removing the silicon substrate layer 111 therefrom. The etching can be carried out by using either an acid or an alkali. From the viewpoint of an etching rate, it is more preferable to carry out the etching with an acid. It is most preferable to carry out the etching by using one or more acids selected from the group of strong acids including HF, HNO₃, CH₃COOH, H₂SO₄, and H₃PO₄, or in particular, by using a mixed acid in which acids, freely selected from the group consisting of these acids, are mixed. It is possible to carry out the etching by immersing the bonded body after being subjected to the edge trimming or by conducting spin etching on one side thereof. The insulator layer 112 is exposed by this step, and then the third substrate 13 is attached to the surface of this insulator layer 112, thereby securing the transmission of light.

(iv) Step of Attaching Third Substrate

In the step (iv), the third substrate 13 is attached to the first substrate 11c that has been thinned in the preceding step (iii). An adhesive used in this step may also be referred to as a transferring adhesive 17. The transferring adhesive 17 is desirably made of a material having light transmissivity in the range of visible light, and an epoxy based adhesive is preferred herein. The light transmissivity in the range of the visible light stated herein may have the same definition as the transparency of the transparent substrate defined earlier. In order not to cause stress deformation of a transferred device, it is preferable to use a low-stress adhesive for the transferring adhesive 17, and it is more preferable to carry out adhesion such that a thickness of the adhesive layer falls in a range from 0.1 μm to not more than 5 μm after curing. In particular, thermosetting epoxy-modified silicone may be favorably used as the adhesive layer 17. The use of this adhesive layer 17 makes it possible to achieve the transfer having a small stress and being excellent in heat resistance while retaining the light transmissivity in the range of visible light. The transferring adhesive 17 can be coated on the thinned first substrate 11c or on the third substrate (a transfer substrate) side. Nonetheless, it is more preferable to coat the adhesive on the third substrate 13. FIG. 1(g) schematically illustrates a bonded body of the second substrate 12, the thinned first substrate 11c, and the third substrate 13, obtained in this step.

(v) Step of Removing Second Substrate From First Substrate

Subsequently, the temporarily bonded second substrate 12 is detached and removed from the thinned first substrate 11c (FIG. 1(h)). When detaching the second substrate 12 from the first substrate 11c, an opening is formed by inserting a blade 18 into a portion of the transferring adhesive 17 on the bonded surfaces of the first substrate 11 and the second substrate 12 while applying forces F for pulling the second substrate 12 and the third substrate 13 away from each other, and then the substrates are detached at the portion of the transferring adhesive 17 by continuously applying the pulling forces F.

(vi) Step of Exposing Surface of Circuit Layer

The step (vi) is a step of removing the transferring adhesive 17 remaining on the surface of the first substrate 11c after the detachment of the second substrate 12 by using an organic solvent. One skilled in the art can appropriately select the organic solvent depending on the type of transferring adhesive 17 and other factors. In the case of using the transferring adhesive 17 composed mainly of the thermosetting epoxy-modified silicone, for example, it is possible to employ an organic solvent and the like such as p-menthane. In this way, it is possible to transfer the circuit layer of the micro display formed on the superficial layer of the first substrate 11c onto the third substrate 13, thereby manufacturing the micro display board. FIG. 1(i) is a diagram schematically illustrating the micro display board 20 thus obtained.

### Second Embodiment: Transmissive Micro Display Board

A second embodiment of the present invention relates to a transmissive micro display board. This transmissive micro display board is a transmissive micro display board including an insulating layer originating from an SOI wafer and a circuit layer, which are stacked, in this order, on a transparent substrate by using an adhesive. Here, the circuit layer includes an active layer, a gate layer, and a wiring layer on the insulating layer, and the wiring layer forms a light shielding layer by being provided to satisfy such a positional relationship that the wiring layer shields the active layer and the gate layer from incident light from an opposite side of the transparent substrate.

The transmissive micro display board of this embodiment is typically the micro display board 20 illustrated in FIG. 1(i), which is manufactured in accordance with the manufacturing method according to the first embodiment. Its structure and use applications have been described in conjunction with the first embodiment, and explanations thereof will be omitted herein. Note that the circuit layer may include a pixel electrode layer formed on a surface on an opposite side of the gate layer of the wiring layer, and the pixel electrode layer may be a transparent electrode such as an ITO film. The transmissive micro display board can be used as a component of a micro display liquid crystal panel.

### EXAMPLE

The present invention will be specifically described below by way of examples. It is to be noted, however, that the present invention shall not be limited only to these examples.

### Example 1

An SOI substrate having an outside diameter of 200 mm and a thickness of 725 μm was prepared. The SOI substrate was formed from the single-crystal silicon layer as the superficial layer, the insulating layer made of the buried oxide film, and the silicon substrate layer. The circuits were formed in the single-crystal silicon layer having a thickness of 150 nm in accordance with the semiconductor process. The active layer 21 of each transistor was arranged as illustrated in FIG. 4, The gate layer 22 thereof was arranged as illustrated in FIG. 5. The first, wiring layer 23 as the metal layer was arranged as illustrated in FIG. 6, and the second wiring layer 24 as the metal layer was arranged as illustrated in FIG. 7. Thus, the circuit was designed in such a way as to cover the transistor region with the metal layers. The region of ITO of the transparent electrode serving as the pixel electrode 34 was arranged as illustrated in FIG. 9.

An ITO (indium-tin-oxide) film was deposited on the surface of the SOI substrate provided with the circuit as designed, then the pixel electrode was formed by providing the ITO film with grooves in such a way as to separate the pixels from one another after depositing the film. The first substrate was thus obtained.

Substrates each made of synthetic quartz glass having an outer diameter of 200 mm and a thickness of 725 μm were prepared as the second substrate and the third substrate. An adhesive at the time of the temporary bonding to attach the first substrate to the second substrate was selected in consideration of workability at the time of later detachment and heat resistance at the time of a thermal treatment after bonding the third substrate. Here, TA1070T, TA2570V3, and TA4070 being the thermosetting modified silicone-based adhesives manufactured by Shin-Etsu Chemical Co., Ltd., were used. By means of spin coating, TA1070T in a thickness of 10 μm was coated on the circuit in the first substrate, then TA2570V3 in a thickness of 10 μm was coated on thereon, and then TA4070 in a thickness of 90 μm was further coated thereon, and the adhesives in a total thickness of 110 μm were thus deposited. Here, TA1070T has a function to protect the circuit, TA2570V3 has a function to serve as a detachment layer when separating the substrates, and TA4070 has a function to serve as an adhesive layer to the second substrate. As for the attachment of the second substrate, the second substrate was pressed against the adhesive layer while applying a force of 0.1 MPa, then horizontally set in an oven while leaving a jig attached thereto, and then subjected to a thermal treatment for 2 hours at 190° C. to cure the adhesive.

Next, the silicon substrate layer of the first substrate to which the second substrate was temporarily attached was ground with a grinding wheel until the thickness of the first substrate was reduced to 30 μm by using Polish Grinder PG300 manufactured by Tokyo Seimitsu Co., Ltd. After the grinding, the remaining silicon substrate layer in the thickness of 30 μm was removed by spin etching with an acid by using Spin Etcher MSE 2000 manufactured by Mimasu Semiconductor Industry Co., Ltd. An etchant used herein was a mixed acid of HF/HNO₃/H₃PO₄/H₂SO₄. The buried oxide film was exposed by completely removing the silicon substrate layer in an etching period of 2 minutes.

Next, the third substrate made of synthetic quartz glass was attached to the first substrate having the exposed buried oxide film by use of an adhesive. Here, TA4070 being the epoxy-modified silicone adhesive, diluted with cyclopentanone and thus adjusted to an adhesive concentration of 0.5 wt %, was used as the adhesive. This adhesive was spin-coated on the third substrate and formed into the adhesive layer having a thickness of 1 μm. The third substrate coated with the adhesive was subjected to removal of the solvent and half cuffing by conducting a thermal treatment for 5 minutes at 150° C. The third substrate subjected to half curing was attached to the thinned substrate by using Wafer Bonder Synapse Si manufactured by Tokyo Electron, Ltd. The attachment was carried out by raising the temperature to 190° C., applying a load of 3 kgf/cm², and holding the substrates at 130° C. under vacuum for 10 minutes The attached substrates were taken out and obtained after the substrates were cooled.

Next, the temporarily bonded second substrate was detached. Using a dedicated detachment apparatus, the substrates were placed on a suction chucking stage in such a way as to locate a rear surface of the third substrate (a surface not in contact with the first substrate) at the bottom and to locate a rear surface of the second substrate (a surface not in contact with the first substrate) on the top. Thereafter, a suctioning tool provided with a mechanism for pulling upward was attached to the rear surface of the second substrate in the state of suctioning the third substrate, and then a force was applied in a direction to pull the second substrate and the third substrate away from each other. Then, a blade was inserted into the adhesive layer serving as an interface between the first substrate and the second substrate while continuously applying force. An opening was formed at a portion of the adhesive layer as a consequence of insertion of the blade. Since the force to pull the substrates away from each other was being applied thereto, the opening gradually widened and the detachment progressed. Eventually, the second substrate was detached from the first substrate starting from a portion attached thereto with the adhesive, and the detachment of the second substrate was thus completed. In this instance, the third substrate was not detached from the first substrate.

After the detachment of the second substrate, the adhesive remaining on the first substrate was removed by immersing the first substrate in an organic solvent containing p-menthane for 5 minutes. A bonding interface of the first substrate bonded to the third substrate could not be confirmed directly with the eye, and a portion not provided with the circuits was transparent. Note that the definition of transparency stated herein is the same as the definition of transparency in terms of the third substrate.

A sealing adhesive was coated by screen printing on the micro display board thus obtained. Then, a glass substrate with its entire surface provided with an ITO film, which was prepared separately as a counter substrate, was attached to the micro display board. Thereafter, the sealing material was cured while maintaining an interval between the micro display board and the counter substrate so as to form a prescribed gap. After the sealing material was cured, panels were obtained by dicing the attached wafer one by one into the panels. Each panel was filled with the liquid crystal in vacuum, and the display liquid panel was thus obtained.

Polarization plates were placed on two sides in the thickness direction of the liquid crystal panel and then its operation was checked. The panel achieved fine display even in the case of irradiation with a light source at 50,000 cd/m³ and no effects of photo-leakage currents were observed.

### REFERENCE SYMBOL LIST

11a a first substrate
11b first substrate provided with circuit layer
11c thinned first substrate
111 silicon substrate layer
112 insulator layer
113 single-crystal silicon layer
113′ circuit layer (layer including active layer obtained by doping single-crystal silicon layer with impurity, gate layer formed on front surface thereof, and wiring layer)
12 second substrate
13 third substrate
16 temporary bonding adhesive
17 transferring adhesive
18 blade
21 active layer
22 gate layer
23 first wiring layer
24 second wiring layer
25 wiring
26 insulation film (oxide film)
30 liquid crystal panel
31a, 31b polarization plate
33 circuit
34 pixel electrode
35 liquid crystal
36 sealing material
37 counter electrode
38 counter substrate

1. A manufacturing method for a micro display board, the method comprising the steps of:
(i) forming a circuit layer on a surface of a first substrate provided with a single-crystal silicon layer;
(ii) attaching a second substrate by using an adhesive to the surface of the first substrate on which the circuit layer has been formed;
(iii) thinning a rear surface of the first substrate;
(iv) attaching a third substrate being a transparent substrate to the thinned surface of the first substrate by using an adhesive;
(v) removing the second substrate from the first substrate; and
(vi) exposing a surface of the circuit layer by removing the adhesive on the surface of the first substrate after detaching the second substrate,
wherein the step of forming a circuit layer on the first substrate includes the steps of forming an active layer, a gate layer, and a wiring layer, and
wherein the wiring layer forms a light shielding layer by being provided to satisfy such a positional relation that the wiring layer shields the active layer and the gate layer from incident light from an opposite side of the active layer.

2. The manufacturing method according to claim 1, wherein the first substrate is a silicon on insulator (SOI) substrate including a single-crystal silicon layer, an insulating layer, and a silicon substrate layer.

3. The manufacturing method according to claim 2, wherein the step of thinning includes the steps of
grinding while leaving a portion of the silicon substrate layer, and
removing the silicon substrate layer by etching until the insulating layer is exposed, and
the step of attaching the third substrate includes the step of attaching the insulating layer to the third substrate.

4. The manufacturing method according to claim 1, wherein the third substrate is a glass substrate.

5. The manufacturing method according to claim 4, wherein the glass substrate is a quartz glass substrate.

6. A transmissive micro display board comprising:
a transparent substrate;
an insulating layer originating from an SOI wafer; and
a circuit layer,
wherein the insulating layer and the circuit layer are stacked, in this order, on the transparent substrate by using an adhesive,
the circuit layer includes an active layer, a gate layer, and a wiring layer, which are located on the insulating layer, and
the wiring layer forms a light shielding layer by being provided to satisfy such a positional relation that the wiring layer shields the active layer and the gate layer from incident light from an opposite side of the transparent substrate.
